(19) United States
(12) Patent Application Publication
(10) Pub. No.: US 2026/0291625 A1
(43) Pub. Date: Sep. 24, 2026

(54) LOW COST ON-CHIP BUILT-IN SELF-TEST ARCHITECTURE FOR MILLIMETER WAVE RADIO FREQENCY INTEGRATED CIRCUIT

(71) Applicant: Samsung Electronics Co., Ltd., Gyeonggi-do (KR)

(72) Inventors: Mingyuan LI, San Jose, CA (US); Omar ELSAYED, San Jose, CA (US); Amir ESMAILI, Oceanside, CA (US); Foad ARFAEI MALEKZADEH, San Diego, CA (US); Siuchuang Ivan LU, San Jose, CA (US)

(21) Appl. No.: 19/369,785

(22) Filed: Oct. 27, 2025

Related U.S. Application Data
(60) Provisional application No. 63/776,776, filed on Mar. 24, 2025.

(51) Int. Cl. H04B 17/19; G01R 31/28; G01R 31/317; H04B 17/11; H04B 17/21

(52) U.S. Cl. CPC H04B 17/19; G01R 31/2822; G01R 31/2856; G01R 31/31727; H04B 17/11; H04B 17/21

(57) ABSTRACT

A system and a method are disclosed for built-in self-test (BIST) for a radio frequency (RF) device including a receiver block and a transmitter block. A method includes injecting a receiver tone at an input of the receiver block of the RF device, calibrating the receiver block based on the receiver tone, injecting a transmitter tone at an input of the transmitter block, and calibrating the transmitter block based on the receiver tone.

### CROSS-REFERENCE TO RELATED APPLICATION

This application claims the priority benefit under 35 U.S.C. § 119(e) of U.S. Provisional Application No. 63/776,776, filed on Mar. 24, 2025, the disclosure of which is incorporated by reference in its entirety as if fully set forth herein.

### TECHNICAL FIELD

The disclosure generally relates to radio frequency integrated circuits (RFICs). More particularly, the subject matter disclosed herein relates to improvements to built-in self-test (BIST) for millimeter wave (mmWave) RFICs, power combiners, couplers, and power detectors (PDETs).

### SUMMARY

The cost of testing RFICs at mmWave frequency with an external equipment set-up may be relatively expensive and time consuming. Over the air (OTA) techniques often require an interference-free environment and not are suitable for chip-level calibration. External equipment-based testing methods often utilize expensive mmWave equipment, and testing is relatively slow (e.g., such testing can have a long calibration and settling time).

On-chip BIST can reduce or eliminate these testing costs, and can provide monitoring of temperature, aging variations, and failures. However, some BIST systems may only target a transmitter (TX) and receiver (RX) working at the same center frequency by using switches or loopback, and thus cannot test different frequencies for the TX and RX. Moreover, such a loopback method may only be applicable to special RFIC architecture. Additionally, some test tone generation methods for mmWave RFIC BIST may suffer from limited frequency range, broadness, and accuracy.

To overcome these types of issues, BIST systems and methods are described herein for an RF device. According to an embodiment, for a tone generator, a high quality test tone (e.g., a test tone having low phase noise or high signal-to-noise ratio (SNR)) may not be necessary. Rather, a small area, low cost, low frequency oscillator may be used with frequency multipliers to provide test tones for the TX and RX with different frequencies. Some existing BIST systems may only target a TX and RX working at the same center frequency by using switches or loopback, and cannot test different frequencies for the TX and RX.

According to the disclosed embodiments, the core of a tone generator can be shared between the TX and RX. A wide bandwidth at different center frequency can be achieved with a proper frequency plan with frequency multipliers.

Some embodiments may use a symmetrical test tone distribution network (e.g., having independent TX and RX paths, rather than a loopback as in the example FIG. 1 below) to connect a clock signal (CLK) to TX and RX. This symmetry may allow for calibration of different phase array channels. Some embodiments may use CLK repeaters to amplify the CLK strength to achieve low process, voltage, and temperature (PVT) variations.

Some embodiments may use a programmable capacitive coupler to provide flexible coupling signal to a low noise amplifier (LNA; e.g., an efficient amplifier for low-power signals) input with minimal noise FIGURE(NF) degradation (e.g., minimal degradation of SNR as measured by ratio of input SNR to output SNR), for example less than 1 dB. Some embodiments may use hybrid (e.g., Wilkinson and/or T-Junction) power combiners/splitters to provide test tone to multi channels with balanced consideration of area and isolation. Some embodiments may use PDETs at BIST and RX/TX output to calibrate the power, gain, BW etc.

These approaches, described in greater detail herein, improve on previous methods because, according to some embodiments, BIST may not affect the RFIC performance in normal mode, may not use excessive added hardware (e.g., die size, function blocks), may be relatively flexible, may be relatively fast, and may be utilized or incorporated in a system level.

Further, in some embodiments, the BIST architecture can be introduced with a low cost on-chip shared wideband tone generator, low variation repeater, programmable coupler, and hybrid power combiners and splitters.

In an embodiment, a method comprises injecting a receiver tone at an input of the receiver block of the RF device, calibrating the receiver block based on the receiver tone, injecting a transmitter tone at an input of the transmitter block, and calibrating the transmitter block based on the receiver tone.

In an embodiment, an RF device comprises a receiver block, a transmitter block, and a BIST unit, wherein the BIST unit is configured to inject a receiver tone at an input of the receiver block of the RF device, calibrate the receiver block based on the receiver tone, inject a transmitter tone at an input of the transmitter block, and calibrate the transmitter block based on the transmitter tone.

### BRIEF DESCRIPTION OF THE DRAWING

In the following section, the aspects of the subject matter disclosed herein will be described with reference to exemplary embodiments illustrated in the figures, in which:

FIG. 1 is a circuit diagram showing an example BIST unit.

FIG. 2 is a block diagram of a symmetrical test tone distribution network for a BIST unit, according to an embodiment.

FIG. 3 is a circuit diagram showing BIST circuitry within an RFIC, according to an embodiment.

FIG. 4 is a block diagram of a capacitive coupler with a programmable attenuator, according to an embodiment.

FIG. 5 is a flow diagram illustrating a BIST method for an RF device, according to an embodiment.

FIG. 6 is a block diagram of an electronic device in a network environment, according to an embodiment.

FIG. 7 shows a system including a UE and a gNB in communication with each other.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures(including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “module” refers to any combination of software, firmware and/or hardware configured to provide the functionality described herein in connection with a module. For example, software may be embodied as a software package, code and/or instruction set or instructions, and the term “hardware,” as used in any implementation described herein, may include, for example, singly or in any combination, an assembly, hardwired circuitry, programmable circuitry, state machine circuitry, and/or firmware that stores instructions executed by programmable circuitry. The modules may, collectively or individually, be embodied as circuitry that forms part of a larger system, for example, but not limited to, an integrated circuit (IC), system on-a-chip (SoC), an assembly, and so forth.

The cost of testing RFICs at mmWave frequency with an external equipment set-up may be relatively expensive and time consuming. OTA techniques may require an interference-free environment and are not suitable for chip-level calibration. Many other approaches to testing mmWave RFICs either involve an external calibration path or an internal feedback loop. An external equipment-based testing method may utilize expensive mmWave equipment, and testing is relatively slow (e.g., equipment-based testing can have a long calibration and settling time).

On-chip BIST can greatly reduce or eliminate these testing costs, and can provide monitoring of temperature, aging variations, and failures. However, some BIST systems may only target a TX and an RX operating at the same center frequency by using switches or loopback (e.g., an internal feedback loop), and thus cannot test different frequencies for the TX and RX. In addition, such a loopback method may only be applicable to special RFIC architecture. Some test tone generation methods for mmWave RFIC BIST may also suffer from limited frequency range, broadness, and accuracy.

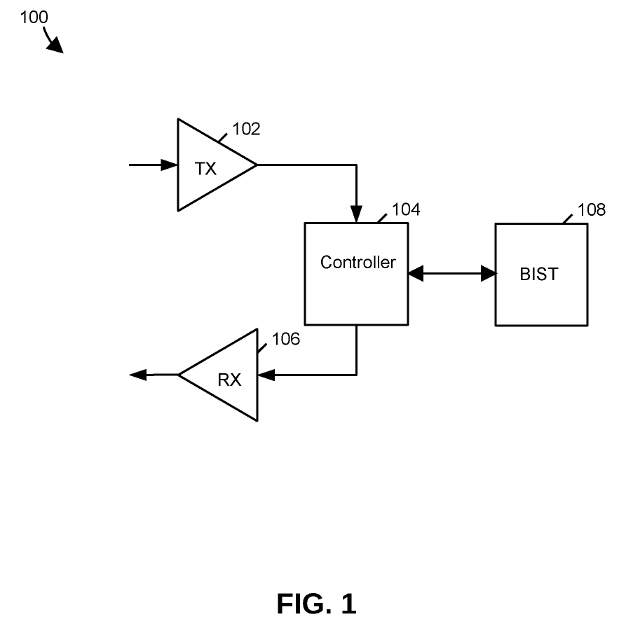

FIG. 1 is a circuit diagram 100 showing an example BIST unit 108 using a loopback method.

Referring to FIG. 1, TX 102 produces a signal that is then passed to controller 104, which is in communication with BIST 108 for testing purposes. The test tone signal is then passed from controller 104 to RX 106. For example, the signal originating from TX 102 can be looped back to RX 106 and used as a test tone for calibrating RX 106. Accordingly, the test tones used by BIST 108 to calibrate both TX 102 and RX 106 must have the same frequency. If TX 102 and RX 106 operate at different center frequencies, then they cannot both be tested by circuit 100.

Accordingly, there is a need for a BIST unit that can calibrate a TX and RX operating at different center frequencies. At the same time, the BIST unit should not require excessive added hardware (e.g., by requiring separate tone generators for the TX 102 and RX 106, or other hardware such as die size, function blocks, filters, or power splitters). In addition, it is desirable for the BIST unit not to affect the original RFIC performance, to be flexible (e.g., to allow for a difference between the TX and RX center frequencies, to provide multiple testing modalities, and/or to accommodate different testing frequencies), to operate fast (e.g., not to require operation, actuation, or preparation of external equipment), and to be considered at a system level. Finally, it is desirable for BIST architecture to be introduced with a low cost on-chip shared wideband (e.g., providing a broad testing frequency range) tone generator (e.g., a low frequency oscillator capable of generating a clock signal), low variation repeater (e.g., a CLK repeater to amplify the CLK strength to achieve low PVT variations), programmable coupler (e.g., circuitry that can directionally transfer a programmable amount of input power to an output port) and hybrid power combiners and splitters (e.g., circuitry that can bi-directionally transfer half the input power between two ports). The disclosed system and methods can solve these problems by using a small area, low cost, low-frequency oscillator with frequency multipliers to provide test tones for TX and RX having different frequencies via a symmetrical test tone distribution network, as described herein.

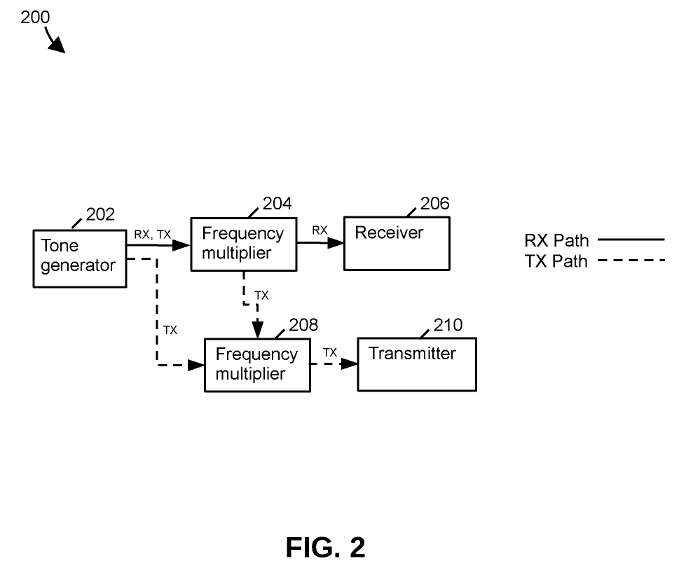

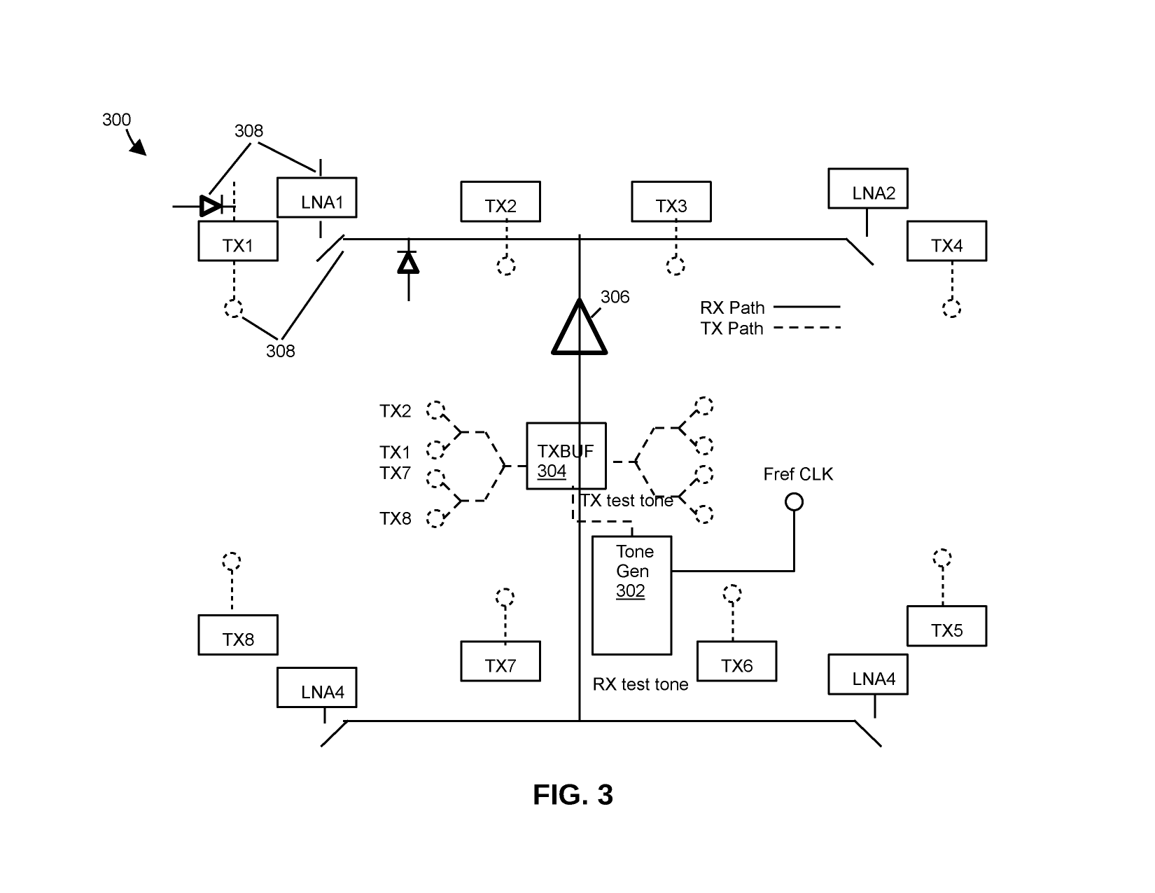

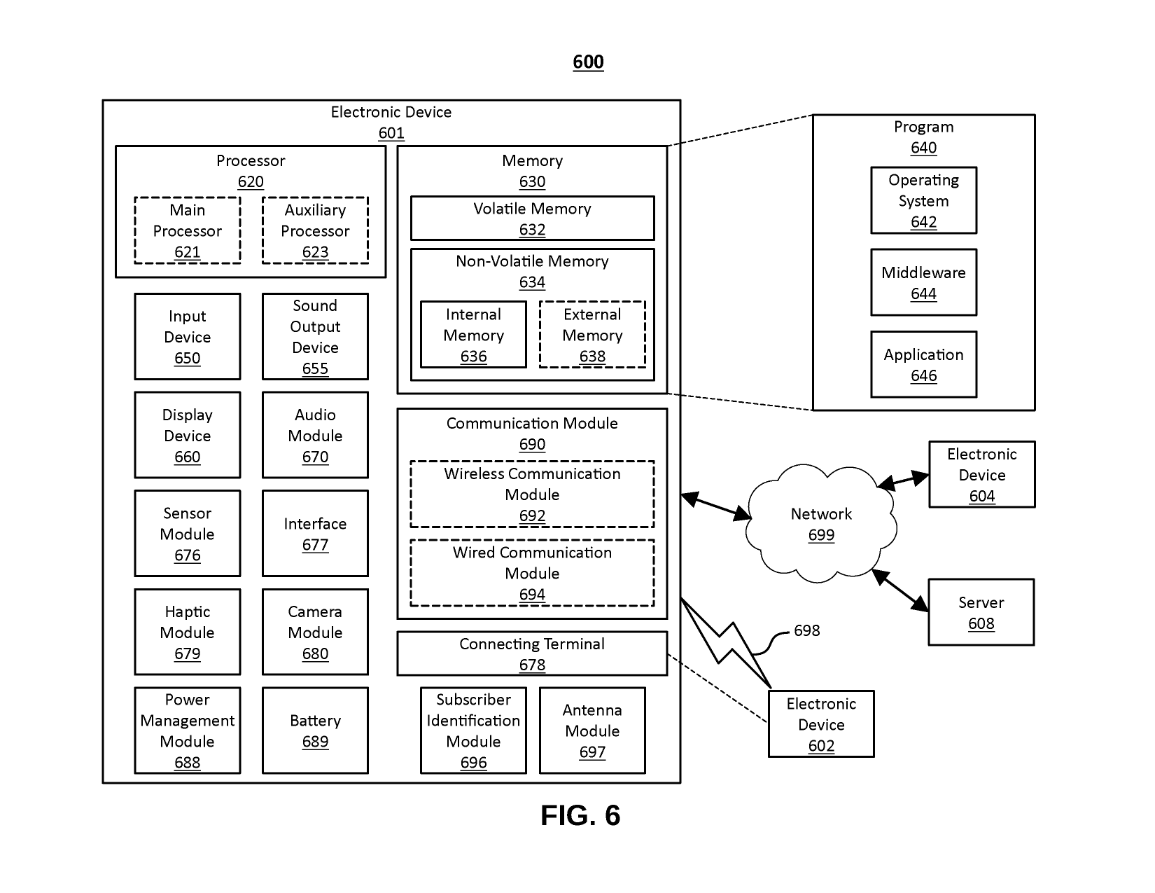

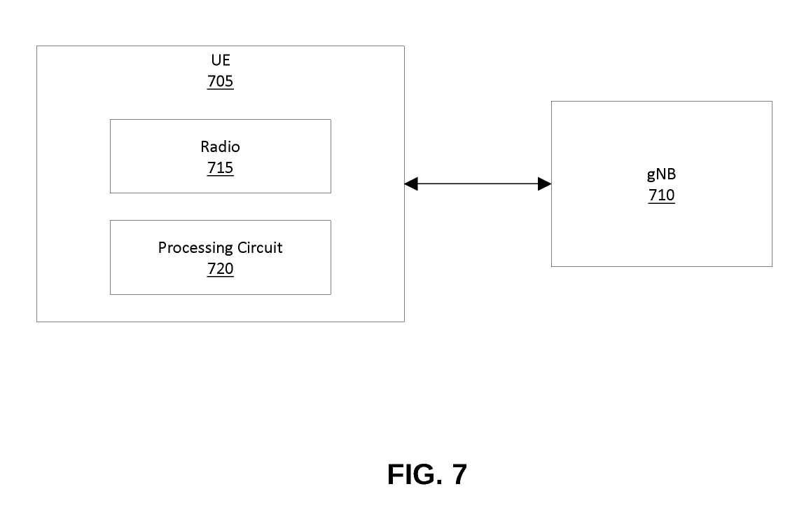

FIG. 2 is a block diagram of a test tone distribution network 200 (e.g., a conductive path for testing) having symmetry for a BIST unit, according to an embodiment. In various examples, the test tone distribution network 200 may be part of a mmWave RFIC and/or an Ultra High Frequency (UHF) RFIC such as the RFIC 300 of FIG. 3 below, an RFIC with a different frequency range, another RF device, another electronic device such as the electronic device 601 of FIG. 6, and/or a UE such as the UE 705 of FIG. 7. This device may include a BIST unit, which may further include the test tone distribution network 200.

Referring to FIG. 2, the tone generator 202 can generate a test tone signal, which can be used to calibrate the receiver 206 (e.g., a receiver block or a circuit block including RFIC circuitry for receiving radio signals, such as wireless communication module 692, communication module 690, radio 715 of the examples of FIGS. 6-7, or other receiver circuitry) and transmitter 210 (e.g., a transmitter block or a circuit block with RFIC circuitry for transmitting radio signals, such as wireless communication module 692, communication module 690, radio 715 of the examples of FIGS. 6-7, or other transmitter circuitry). For example, the tone generator 202 can inject test tone signals at the inputs of the to-be-calibrated receiver block 206 and transmitter block 210, rather than using a loopback to RX, as in the example of FIG. 1, external equipment, or OTA techniques. Because the test tone distribution network 200 is symmetrical (e.g., the TX and RX paths are independent rather than looping back as in the example of FIG. 1), the tone generator 202 can send the test tone signal to both the receiver 206 and transmitter 210, e.g. the core of tone generator 202 can be shared between them. This symmetry can provide important advantages, such as enabling calibration of different phase array channels, and reducing the quantity and expense of hardware needed for BIST. For example, the tone generator 202 may use a small area, low cost, low frequency oscillator (e.g., clock signal) to generate the test tone.

In some cases, the test tone may be a pure tone, e.g., a pure frequency signal. However, in some embodiments, the tone generator 202 may have a wider bandwidth so as to cover the TX and RX paths. For example, the tone generator 202 may have a sufficiently wide bandwidth so as to input different initial frequencies into the various TX and RX paths in order to provide different final receiver tone (e.g., a pure-frequency signal after suitable frequency multiplication used for testing the receiver 206) and transmitter tone (e.g., a pure-frequency signal after suitable frequency multiplication used for testing the transmitter 210). For example, the tone generator 202 may generate a tone sweeping its frequency, so as to cover a certain bandwidth.

In some embodiments, a wide bandwidth at different center frequencies for receiver 206 and transmitter 210 can be achieved with a proper frequency plan using frequency multipliers. For example, the generated test tone may be passed from tone generator 202 along test tone distribution network 200 through frequency multipliers 204 and 208, thereby enabling the test tone distribution network 200 to provide test tones with different frequencies to the receiver 206 and transmitter 210. In this example, the RX path runs through frequency multiplier 204 to receiver 206. A first TX path runs from tone generator 202, through frequency multiplier 208, and finally to transmitter 210. In some cases, the frequency multipliers 204 and 208 may multiply the frequency by different factors, for example doubling and quadrupling, or by factors of 20 and 60, as in the example above, and therefore the final test tone reaching transmitter 210 is different from the one reaching receiver 206, without the need for a second tone generator or extensive hardware.

In addition, a second TX path runs from tone generator 202, through frequency multiplier 204, then also through frequency multiplier 208, and finally to transmitter 210. In some cases, when the test tone follows this second TX path, it is modified (e.g., frequency multiplied) by both frequency multipliers 204 and 208, so the final test tone reaching transmitter 210 is different from the one reaching receiver 206, without the need for a second tone generator or extensive hardware. In some embodiments, the presence of the two TX paths enables test tone distribution network 200 to modulate the final test tone frequency reaching transmitter 210, for example via switching and/or mixing.

The test tone may be a pure frequency signal, and may also be referred to as a clock signal (CLK). In some embodiments, the tone generator 202 may be configured to alter the test tone it generates, so as to test receiver 206 and transmitter 210 at different frequencies. However, the frequency multipliers 204 and 208 may perform fixed frequency multiplication.

FIG. 3 is a circuit diagram showing BIST circuitry within an RFIC 300, according to an embodiment. In various examples, the RFIC 300 may correspond to a mmWave RFIC, a UHF RFIC, an RFIC with another frequency range, and/or another RF device, and/or be part of another electronic device such as the electronic device 601 of FIG. 6, or a UE such as the UE 705 of FIG. 7. The RFIC 300 may include a BIST unit, as described in this example.

Referring to FIG. 3, similar to the example of FIG. 2, the RFIC 300 may have a symmetrical test tone distribution network to connect CLK (e.g., tone generator 302) to TX and RX. The symmetrical test tone distribution network can include both a TX path (shown as a dashed line) and an RX path (solid line). This symmetry can be important for calibration of different phase array channels. Accordingly, the tone generator 302 can inject test tone signals at the inputs of the to-be-calibrated receiver and transmitter blocks, as described in the example of FIG. 2 above.

The RFIC 300 may include a plurality of transmitters and receivers, as may be typical for a mmWave RFIC. In this example, the TX path includes transmitters (e.g., transmitter blocks) TX1 through TX8. Likewise, the RX path may also include multiple receivers (not shown). The TX path may include a TX buffer (TXBUF) 306, and may then lead to transmitters TX1 through TX8. In particular, the references to TX1 through TX8 illustrated in the center of FIG. 3 can lead to the corresponding transmitters, TX1 through TX8, shown at the top and bottom of FIG. 3.

The symmetry of the test tone distribution network 200 may be important for calibration of different phase array channels. In some examples, the BIST circuitry may be used to test multiple TX paths, for example the paths leading to transmitters TX1 and TX2. Utilizing the symmetrical test tone distribution network, the system can inject the same test signal (e.g., transmitter tone) to both TX1 and TX2. Accordingly, if TX1 and TX2 have the same output, then both transmitters are believed to have the same performance. In addition, due to the symmetrical test tone distribution network, the converse may also be true: for example, if the outputs of TX1 and TX2 are found to be different, the performance of TX1 and TX2 may be concluded to differ from each other, since the input (e.g., the injected test signal) is the same. Likewise, when testing multiple RX paths, such as the paths leading to receivers RX1 and RX2, the symmetry of the test tone distribution network may imply that RX1 and RX2 have the same performance if and only if they have the same output.

According to some embodiments, the BIST circuitry may not affect the performance of RFIC 300 in normal mode, may not use excessive added hardware (e.g., die size, function blocks), may be relatively flexible, may be relatively fast, and may be utilized or incorporated at a system level.

In some examples, the RFIC 300 can use hybrid Wilkinson and T-Junction power combiners/splitters to provide a test tone to multiple channels with balanced consideration of area and isolation. For example, these may be located along the TX and/or RX paths, between the tone generator 302 and the TX and/or RX blocks.

In an embodiment, the RFIC 300 can use CLK repeaters 306 to amplify the CLK strength to saturation so as to achieve low PVT variations. For example, the repeaters 306 may operate in the regime of power saturation to amplify the test tone signal strength. In an example, this may mean that the repeaters 306 amplify the CLK strength to their saturated (e.g., minimum or maximum) output values, such as the power supply voltage of repeaters 306. As a result, the output of repeaters 306 may be clipped to such a minimum or maximum value, thereby reducing variations due to PVT.

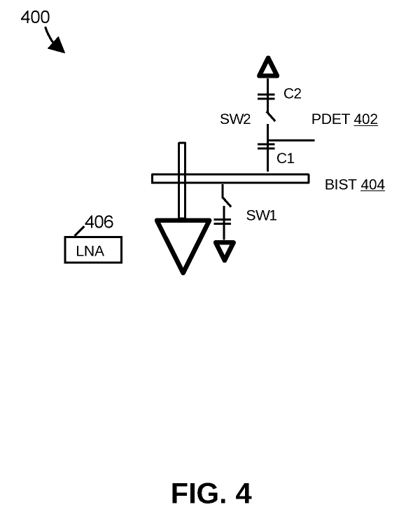

The RFIC 300 may also include a plurality of LNAs (e.g., efficient amplifiers for low-power signals), such as LNA1 through LNA4, as shown. In some embodiments, one or more of these LNAs can use a programmable capacitive coupler to provide flexible coupling signal to the LNA input with minimal NF degradation (e.g., minimal degradation of SNR as measured by ratio of input SNR to output SNR). This is described in greater detail in the example of FIG. 4 below. RFIC 300 can also include PDETs 308 (e.g., sensor and measurement circuitry that can monitor voltage and current levels), for example at the BIST and RX/TX output, which RFIC 300 can use to calibrate the power, gain, bandwidth, and the like.

In some examples, RFIC 300 may include additional circuitry (not shown), such as an analog-to-digital converter (ADC) and/or a microcontroller unit (MCU), and is not limited by the present disclosure. For example, the RFIC 300 can include an ADC, which can convert the analog output signal of the PDETs 308 into a digital signal. In addition, the RFIC 300 may include an MCU, which can receive the digital signal from the ADC, and process the digital signal in order to implement BIST-related controls.

FIG. 4 is a block diagram of a capacitive coupler 400 with a programmable attenuator, according to an embodiment.

Referring to FIG. 4, some embodiments may use the capacitive coupler 400 with a programmable attenuator to maintain a constant coupling signal strength to the LNA 406 input and contribute little NF degradation.

In this example, the capacitive coupler may include capacitors C1 and C2 and switches SW1 and SW2, and may couple the BIST 404 to PDET 402 and LNA 406, so as to provide flexible signal strength to the inputs of PDET 402 and LNA 406.

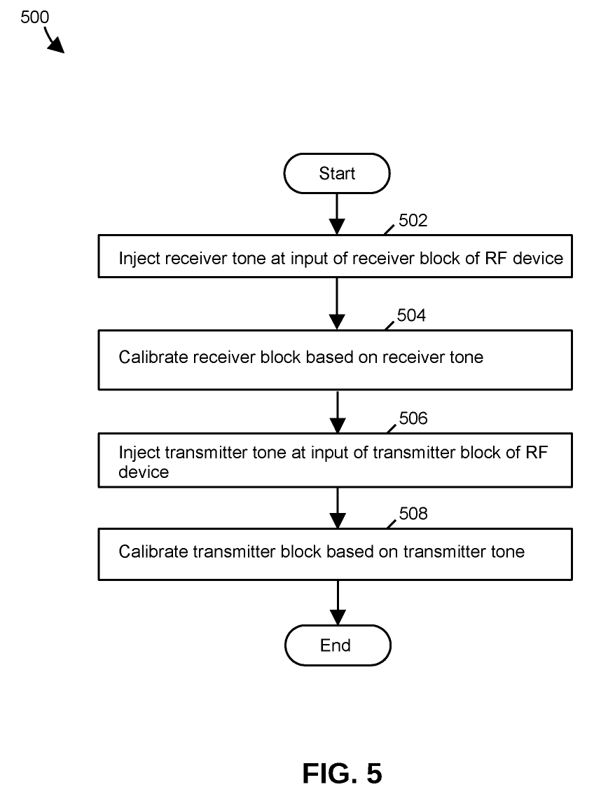

FIG. 5 is a flow diagram illustrating a built-in self-test (BIST) method 500 for a radio frequency (RF) device, according to an embodiment.

Referring to FIG. 5, the method 500 can be performed by a mmWave RFIC such as the RFIC 300 of FIG. 3, a UHF RFIC, an RFIC with a different frequency range, another RF device, or another electronic device such as the electronic device 601 of FIG. 6, and/or by a UE such as the UE 705 of FIG. 7. This device may include a BIST unit, which may further include a tone generator configured to generate a test tone, a symmetrical test tone distribution network, and frequency multipliers configured to convert the test tone (e.g., by multiplying its frequency) to a receiver tone or transmitter tone, as in the examples of FIGS. 2-3. For example, the tone generator may include a small area, low-frequency oscillator. In an example, the BIST unit may also include a power combiner and/or power splitter configured to transmit the test tone to a receiver channel and/or a transmitter channel. In another example, the BIST unit may include clock signal repeaters configured to amplify a clock signal strength (e.g., from the oscillator) to saturation so as to achieve low variations in PVT. In still another example, the BIST unit may include a programmable capacitive coupler configured to provide a flexible coupling signal to an input of an LNA with minimal NF degradation.

Referring to FIG. 5, the method 500 can begin with the system injecting at 502 a receiver tone at an input of the receiver block of the RF device. As shown in the examples of FIGS. 2-3, the tone generator may be connected to the receiver and transmitter blocks via a symmetrical test tone distribution network. The system can inject at 502 the receiver tone along an RX path of the test tone distribution network, which may include frequency multipliers.

In some examples, such frequency multipliers may convert the test tone (e.g., by multiplying its frequency) to the receiver tone. Accordingly, the system may make use of a low cost, low frequency on-chip shared wideband tone generator to generate the receiver tone, but can still generate higher-frequency test tones by frequency multiplication.

Next, the system can calibrate at 504 the receiver block based on the receiver tone. In an example, calibrating at 504 the receiver block may be performed in a receiver test mode. For example, the BIST circuitry may measure the frequency response of the receiver block, such as the receiver gain at different center frequencies (e.g., by sweeping the tone generator and/or varying the frequency multiplication path to provide different receiver tones) and -3 dB gain bandwidth.

In some examples, the BIST circuitry may be used to calibrate at 504 multiple RX paths, for example the paths leading to receivers RX1 and RX2. Utilizing the symmetrical test tone distribution network, the system can inject the same test signal (e.g., same receiver tone) to both RX1 and RX2. Accordingly, the symmetry of the test tone distribution network may imply that RX1 and RX2 have the same performance if and only if they provide the same output.

Next, the system can inject at 506 a transmitter tone at an input of the transmitter block. In some embodiments, the tone generator may be connected to the receiver and transmitter blocks via a symmetrical test tone distribution network. For example, the same tone generator may be used to inject at 506 a transmitter tone at an input of the transmitter block that was previously used to inject at 502 a receiver tone at an input of the receiver block. The system can inject at 502 the receiver tone along a TX path of the test tone distribution network, which may include frequency multipliers.

In some examples, such frequency multipliers may convert the test tone (e.g., by multiplying its frequency) to the transmitter tone, which may have a different frequency than the receiver tone. Accordingly, the system may make use of a low cost, low frequency on-chip shared wideband tone generator to generate the transmitter tone. For example, the same tone generator used to generate the receiver tone injected at 502 (e.g., by generating a test tone which is subsequently multiplied to produce the receiver tone), may also be shared to generate the transmitter tone injected at 506 (e.g., by generating a test tone which is subsequently multiplied to produce the transmitter tone). In some examples, the receiver tone and the transmitter tone may have wide bandwidths.

In some cases, the test tone may be a pure tone, e.g., a pure frequency signal. However, in some embodiments, the tone generator may have a wider bandwidth so as to cover the TX and RX paths. For example, the tone generator may have a sufficiently wide bandwidth so as to input different initial frequencies into the various TX and RX paths in order to provide different final receiver tone (e.g., a pure-frequency signal after suitable frequency multiplication used for testing the receiver) and transmitter tone (e.g., a pure-frequency signal after suitable frequency multiplication used for testing the transmitter). For example, the tone generator may generate a tone sweeping its frequency, so as to cover a certain bandwidth.

Finally, the system can calibrate at 508 the transmitter block based on the transmitter tone. In an example, calibrating at 508 the transmitter block may be performed in a transmitter test mode. Calibrating at 508 the transmitter block may make use of the calibrated receiver block.

For example, the BIST circuitry may measure the frequency response of the transmitter block, such as the transmitter gain at different center frequencies (e.g., by sweeping the tone generator and/or varying the frequency multiplication path to provide different transmitter tones) and -3 dB gain bandwidth. Alternatively or additionally, the transmitter may be configured to output (e.g., transmit or send) the same test tone that it receives, and this output may be measured by the calibrated receiver block and compared to the actual frequency of the transmitter tone.

In some examples, the BIST circuitry may be used to calibrate at 508 multiple TX paths, for example the paths leading to transmitters TX1 and TX2. Using the symmetrical test tone distribution network, the system can inject the same test signal (e.g., same transmitter tone) to both TX1 and TX2. Accordingly, the symmetry of the test tone distribution network may imply that TX1 and TX2 have the same performance if and only if they provide the same output.

FIG. 6 is a block diagram of an electronic device in a network environment 600, according to an embodiment.

Referring to FIG. 6, an electronic device 601 in a network environment 600 may communicate with an electronic device 602 via a first network 698 (e.g., a short-range wireless communication network), or an electronic device 604 or a server 608 via a second network 699 (e.g., a long-range wireless communication network). The electronic device 601 may communicate with the electronic device 604 via the server 608. The electronic device 601 may include a processor 620, a memory 630, an input device 650, a sound output device 655, a display device 660, an audio module 670, a sensor module 676, an interface 677, a haptic module 679, a camera module 680, a power management module 688, a battery 689, a communication module 690, a subscriber identification module (SIM) card 696, or an antenna module 697. In one embodiment, at least one (e.g., the display device 660 or the camera module 680) of the components may be omitted from the electronic device 601, or one or more other components may be added to the electronic device 601. Some of the components may be implemented as a single integrated circuit (IC). For example, the sensor module 676 (e.g., a fingerprint sensor, an iris sensor, or an illuminance sensor) may be embedded in the display device 660 (e.g., a display).

The processor 620 may execute software (e.g., a program 640) to control at least one other component (e.g., a hardware or a software component) of the electronic device 601 coupled with the processor 620 and may perform various data processing or computations.

As at least part of the data processing or computations, the processor 620 may load a command or data received from another component (e.g., the sensor module 676 or the communication module 690) in volatile memory 632, process the command or the data stored in the volatile memory 632, and store resulting data in non-volatile memory 634. The processor 620 may include a main processor 621 (e.g., a central processing unit (CPU) or an application processor (AP)), and an auxiliary processor 623 (e.g., a graphics processing unit (GPU), an image signal processor (ISP), a sensor hub processor, or a communication processor (CP)) that is operable independently from, or in conjunction with, the main processor 621. Additionally or alternatively, the auxiliary processor 623 may be adapted to consume less power than the main processor 621, or execute a particular function. The auxiliary processor 623 may be implemented as being separate from, or a part of, the main processor 621.

The auxiliary processor 623 may control at least some of the functions or states related to at least one component (e.g., the display device 660, the sensor module 676, or the communication module 690) among the components of the electronic device 601, instead of the main processor 621 while the main processor 621 is in an inactive (e.g., sleep) state, or together with the main processor 621 while the main processor 621 is in an active state (e.g., executing an application). The auxiliary processor 623 (e.g., an image signal processor or a communication processor) may be implemented as part of another component (e.g., the camera module 680 or the communication module 690) functionally related to the auxiliary processor 623.

The memory 630 may store various data used by at least one component (e.g., the processor 620 or the sensor module 676) of the electronic device 601. The various data may include, for example, software (e.g., the program 640) and input data or output data for a command related thereto. The memory 630 may include the volatile memory 632 or the non-volatile memory 634. Non-volatile memory 634 may include internal memory 636 and/or external memory 638.

The program 640 may be stored in the memory 630 as software, and may include, for example, an operating system (OS) 642, middleware 644, or an application 646.

The input device 650 may receive a command or data to be used by another component (e.g., the processor 620) of the electronic device 601, from the outside (e.g., a user) of the electronic device 601. The input device 650 may include, for example, a microphone, a mouse, or a keyboard.

The sound output device 655 may output sound signals to the outside of the electronic device 601. The sound output device 655 may include, for example, a speaker or a receiver. The speaker may be used for general purposes, such as playing multimedia or recording, and the receiver may be used for receiving an incoming call. The receiver may be implemented as being separate from, or a part of, the speaker.

The display device 660 may visually provide information to the outside (e.g., a user) of the electronic device 601. The display device 660 may include, for example, a display, a hologram device, or a projector and control circuitry to control a corresponding one of the display, hologram device, and projector. The display device 660 may include touch circuitry adapted to detect a touch, or sensor circuitry (e.g., a pressure sensor) adapted to measure the intensity of force incurred by the touch.

The audio module 670 may convert a sound into an electrical signal and vice versa. The audio module 670 may obtain the sound via the input device 650 or output the sound via the sound output device 655 or a headphone of an external electronic device 602 directly (e.g., wired) or wirelessly coupled with the electronic device 601.

The sensor module 676 may detect an operational state (e.g., power or temperature) of the electronic device 601 or an environmental state (e.g., a state of a user) external to the electronic device 601, and then generate an electrical signal or data value corresponding to the detected state. The sensor module 676 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 677 may support one or more specified protocols to be used for the electronic device 601 to be coupled with the external electronic device 602 directly (e.g., wired) or wirelessly. The interface 677 may include, for example, a high- definition multimedia interface (HDMI), a universal serial bus (USB) interface, a secure digital (SD) card interface, or an audio interface.

A connecting terminal 678 may include a connector via which the electronic device 601 may be physically connected with the external electronic device 602. The connecting terminal 678 may include, for example, an HDMI connector, a USB connector, an SD card connector, or an audio connector (e.g., a headphone connector).

The haptic module 679 may convert an electrical signal into a mechanical stimulus (e.g., a vibration or a movement) or an electrical stimulus which may be recognized by a user via tactile sensation or kinesthetic sensation. The haptic module 679 may include, for example, a motor, a piezoelectric element, or an electrical stimulator.

The camera module 680 may capture a still image or moving images. The camera module 680 may include one or more lenses, image sensors, image signal processors, or flashes. The power management module 688 may manage power supplied to the electronic device 601. The power management module 688 may be implemented as at least part of, for example, a power management integrated circuit (PMIC).

The battery 689 may supply power to at least one component of the electronic device 601. The battery 689 may include, for example, a primary cell which is not rechargeable, a secondary cell which is rechargeable, or a fuel cell.

The communication module 690 may support establishing a direct (e.g., wired) communication channel or a wireless communication channel between the electronic device 601 and the external electronic device (e.g., the electronic device 602, the electronic device 604, or the server 608) and performing communication via the established communication channel. The communication module 690 may include one or more communication processors that are operable independently from the processor 620 (e.g., the AP) and supports a direct (e.g., wired) communication or a wireless communication. The communication module 690 may include a wireless communication module 692 (e.g., a cellular communication module, a short-range wireless communication module, or a global navigation satellite system (GNSS) communication module) or a wired communication module 694 (e.g., a local area network (LAN) communication module or a power line communication (PLC) module). A corresponding one of these communication modules may communicate with the external electronic device via the first network 698 (e.g., a short-range communication network, such as BLUETOOTH^{TM}, wireless-fidelity (Wi-Fi) direct, or a standard of the Infrared Data Association (IrDA)) or the second network 699 (e.g., a long-range communication network, such as a cellular network, the Internet, or a computer network (e.g., LAN or wide area network (WAN)). These various types of communication modules may be implemented as a single component (e.g., a single IC), or may be implemented as multiple components (e.g., multiple ICs) that are separate from each other. The wireless communication module 692 may identify and authenticate the electronic device 601 in a communication network, such as the first network 698 or the second network 699, using subscriber information (e.g., international mobile subscriber identity (IMSI)) stored in the subscriber identification module 696.

The antenna module 697 may transmit or receive a signal or power to or from the outside (e.g., the external electronic device) of the electronic device 601. The antenna module 697 may include one or more antennas, and, therefrom, at least one antenna appropriate for a communication scheme used in the communication network, such as the first network 698 or the second network 699, may be selected, for example, by the communication module 690 (e.g., the wireless communication module 692). The signal or the power may then be transmitted or received between the communication module 690 and the external electronic device via the selected at least one antenna.

In various examples, the communication module 690, wireless communication module 692, and/or antenna module 697 may include an RFIC and/or BIST circuitry, as described herein above. For example, the receiver 206 and/or transmitter 210 of FIG. 2 may correspond to communication module 690 and/or wireless communication module 692 of this example. Similarly, the transmitters TX1 through TX8 and/or the multiple receivers (not shown) of the example of FIG. 3 may correspond to communication module 690 and/or wireless communication module 692. The transmitters and/or receivers performing method 500 of FIG. 5 may also correspond to communication module 690 and/or wireless communication module 692.

Commands or data may be transmitted or received between the electronic device 601 and the external electronic device 604 via the server 608 coupled with the second network 699. Each of the electronic devices 602 and 604 may be a device of a same type as, or a different type, from the electronic device 601. All or some of operations to be executed at the electronic device 601 may be executed at one or more of the external electronic devices 602, 604, or 608. For example, if the electronic device 601 should perform a function or a service automatically, or in response to a request from a user or another device, the electronic device 601, instead of, or in addition to, executing the function or the service, may request the one or more external electronic devices to perform at least part of the function or the service. The one or more external electronic devices receiving the request may perform the at least part of the function or the service requested, or an additional function or an additional service related to the request and transfer an outcome of the performing to the electronic device 601. The electronic device 601 may provide the outcome, with or without further processing of the outcome, as at least part of a reply to the request. To that end, a cloud computing, distributed computing, or client-server computing technology may be used, for example.

FIG. 7 shows a system including user equipment (UE) 705 and a gNB 710, in communication with each other.

Referring to FIG. 7, the UE may include a radio 715 and a processing circuit (or a means for processing) 720, which may perform various methods disclosed herein, e.g., the method illustrated in FIG. 1. For example, the processing circuit 720 may receive, via the radio 715, transmissions from the network node (gNB) 710, and the processing circuit 720 may transmit, via the radio 715, signals to the gNB 710. In various examples, the UE 705 and/or radio 715 may include an RFIC and/or BIST circuitry, as described herein above.

In various examples, the radio 715 and/or UE 705 may include an RFIC and/or BIST circuitry, as described herein above. For example, the receiver 206 and/or transmitter 210 of FIG. 2 may correspond to radio 715 of this example. Similarly, in some embodiments, the transmitters TX1 through TX8 and/or the multiple receivers (not shown) of the example of FIG. 3 may correspond to radio 715. In an embodiment, the transmitters and/or receivers performing method 500 of FIG. 5 may also correspond to radio 715.

Embodiments of the subject matter and the operations described in this specification may be implemented in digital electronic circuitry, or in computer software, firmware, or hardware, including the structures disclosed in this specification and their structural equivalents, or in combinations of one or more of them. Embodiments of the subject matter described in this specification may be implemented as one or more computer programs, i.e., one or more modules of computer-program instructions, encoded on computer-storage medium for execution by, or to control the operation of data-processing apparatus. Alternatively or additionally, the program instructions can be encoded on an artificially-generated propagated signal, e.g., a machine-generated electrical, optical, or electromagnetic signal, which is generated to encode information for transmission to suitable receiver apparatus for execution by a data processing apparatus. A computer-storage medium can be, or be included in, a computer-readable storage device, a computer-readable storage substrate, a random or serial-access memory array or device, or a combination thereof. Moreover, while a computer-storage medium is not a propagated signal, a computer-storage medium may be a source or destination of computer-program instructions encoded in an artificially-generated propagated signal. The computer-storage medium can also be, or be included in, one or more separate physical components or media (e.g., multiple CDs, disks, or other storage devices). Additionally, the operations described in this specification may be implemented as operations performed by a data-processing apparatus on data stored on one or more computer-readable storage devices or received from other sources.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. A radio frequency (RF) device, comprising:
a receiver block,
a transmitter block, and
a built-in self-test (BIST) unit, wherein the BIST unit is configured to:
inject a receiver tone at an input of the receiver block of the RF device,
calibrate the receiver block based on the receiver tone,
inject a transmitter tone at an input of the transmitter block, and
calibrate the transmitter block based on the transmitter tone.

2. The RF device of claim 1, wherein the transmitter tone has a different frequency than the receiver tone.

3. The RF device of claim 1, wherein to calibrate the transmitter block comprises to calibrate the transmitter block using the calibrated receiver block.

4. The RF device of claim 1, wherein the BIST unit further comprises:
an oscillator configured to generate a test tone; and
at least one frequency multiplier configured to convert the test tone to the receiver tone or the transmitter tone.

5. The RF device of claim 4, wherein the oscillator comprises a small area, low-frequency oscillator.

6. The RF device of claim 4, further comprising at least one of a power combiner or power splitter configured to transmit the test tone to:
a receiver channel including the input of the receiver block; or
a transmitter channel including the input of the transmitter block.

7. The RF device of claim 4, wherein the oscillator is connected to the receiver block and the transmitter block via a symmetrical test tone distribution network including the at least one frequency multiplier.

8. The RF device of claim 1, wherein:
to calibrate the receiver block is performed in a receiver test mode; and
to calibrate the transmitter block is performed in a transmitter test mode.

9. The RF device of claim 1, wherein the RF device comprises a millimeter-wavelength (mmWave) RF integrated circuit (RFIC).

10. The RF device of claim 1, wherein the receiver tone and the transmitter tone have wide bandwidths.

11. The RF device of claim 1, further comprising a clock signal repeater configured to amplify a clock signal strength to saturation and reduce variation in process, voltage, and temperature (PVT).

12. The RF device of claim 1, further comprising a programmable capacitive coupler configured to provide a flexible coupling signal to an input of a low noise amplifier (LNA) with negligible noise figure (NF) degradation.

13. A radio frequency (RF) built-in self-test (BIST) system, comprising:
a receiver;
a transmitter; and
a built-in self-test (BIST) device, wherein the BIST device is configured to:
inject a receiver tone at an input of the receiver,
calibrate the receiver based on the receiver tone,
inject a transmitter tone at an input of the transmitter, and
calibrate the transmitter based on the transmitter tone.

14. The RF BIST system of claim 13, wherein the transmitter tone has a different frequency than the receiver tone.

15. The RF BIST system of claim 14, wherein the receiver tone and the transmitter tone have wide bandwidths.

16. The RF BIST system of claim 14, further comprising:
an oscillator configured to generate a test tone; and
at least one frequency multiplier configured to convert the test tone to the receiver tone or the transmitter tone.

17. The RF BIST system of claim 13, wherein the BIST device is further configured to calibrate the transmitter using the calibrated receiver.

18. A built-in self-test (BIST) method for a radio frequency (RF) device including a receiver block and a transmitter block, the BIST method comprising:
injecting a receiver tone at an input of the receiver block of the RF device;
calibrating the receiver block based on the receiver tone;
injecting a transmitter tone at an input of the transmitter block; and
calibrating the transmitter block based on the transmitter tone.

19. The BIST method of claim 18, wherein the transmitter tone has a different frequency than the receiver tone.

20. The BIST method of claim 18, wherein calibrating the transmitter comprises calibrating the transmitter block using the calibrated receiver block.
